(19) United States
(12) Patent Application Publication
(10) Pub. No.: US 2026/0090350 A1
(43) Pub. Date: Mar. 26, 2026

(54) METHOD FOR MANUFACTURING A HIGH-DENSITY ELECTRICAL INTERCONNECTION STRUCTURE

(71) Applicant: COMMISSARIAT A L'ENERGIE ATOMIQUE ET AUX ENERGIES ALTERNATIVES, Paris (FR)

(72) Inventors: Stéphan BOREL, Grenoble (FR); Myriam ASSOUS, Grenoble (FR); Carole SOCQUET-CLERC, Grenoble (FR); Renan BOUIS, Grenoble (FR); Arnaud CORNELIS, Grenoble (FR)

(73) Assignee: COMMISSART AL'ENERGIE ATOMIGUE ET AUX ENERGIES ALTERNATIVES, Paris (FR)

(21) Appl. No.: 19/339,788

(22) Filed: Sep. 25, 2025

(30) Foreign Application Priority Data
Sep. 26, 2024 (FR) 24/10313

(51) Int. Cl. H01L 21/768; H01L 21/3105; H01L 21/321

(52) U.S. Cl. CPC H10W 20/062; H10P 52/403; H10P 95/062; H10W 20/057; H10W 20/076; H10W 20/081; H10W 20/092

(57) ABSTRACT

A method for manufacturing an electrical interconnection structure including a step of providing an initial structure including a substrate, an electrically conductive lower element, a cavity formed in the substrate and having an inner wall internally defining an access to the lower element, and an electrically insulating layer; a step of forming an interconnection element in the cavity; and a final polishing step, wherein a portion of the interconnection element and at least one part of the electrically insulating layer are removed simultaneously by chemical-mechanical polishing using a final polishing agent, thereby forming the electrical interconnection structure.

### TECHNICAL FIELD OF THE INVENTION

The present invention concerns a method for manufacturing an electrical interconnection structure, in particular for establishing an electrical connection between two faces of a substrate.

### PRIOR ART

In the field of microelectronics, the reduction in component dimensions is reaching a limit. In order to increase the number of electronic components in a system, research is now moving towards three-dimensional integration. Such integration allows stacking chips in different layers and connecting them by Through Silicon Vias (TSVs).

TSVs are electrical elements formed through the constituent material of the substrate, so as to electrically connect two opposite faces of the substrate. Thus, electrical contacts can be made on a face of the substrate that is opposite the face where, for example, the microelectronic devices are located. Thus, a major advantage of TSVs is that they allow obtaining a more compact structure.

In the case of 3D structures and generally for complex devices, it is advantageous to provide a structure comprising TSVs distributed at high density in the substrate. TSVs are also increasingly used, for example in combination with hybrid bonding, to produce multi-wafer (or multi-substrate) stacks intended for imaging applications in particular. In a “classic” three-layer 3L structure, the TSVs pass through the middle wafer (tier 2) when it is turned over, and allow it to be electrically connected to the upper wafer (tier 3). Manufacturing methods therefore seek to maximize the number of TSVs emerging on one face of the substrate per unit area.

Although current results allow obtaining a very high quantity of TSVs per unit area, this density is limited by various factors arising from the methods used. Firstly, the distance separating two nearby TSVs is constrained by the alignment accuracy of the lithography apparatuses, which imposes a certain clearance between the TSVs and the pads to which they connect. For current applications, however, the accuracies obtained with these apparatuses remain very good and do not significantly penalize the production of high-density TSVs.

A second limitation comes from the etching method in the formation of TSVs. More particularly, the approach called “via last” is an approach considered less expensive for TSV formation. This approach comprises an etching (called “etch back”) step which consists in etching the insulating material at the bottom of the cavity to allow contact to be made with the electronic device on the front face of the substrate. During this step, faceting occurs in the insulating material overhanging the TSV which widens the TSV (in the range of a hundred nanometers per edge). The apparent diameter of the TSV is therefore increased, and the TSVs cannot get closer to each other beyond this widening, otherwise they will be short-circuited.

There is therefore a need to find a method for manufacturing an electrical interconnection structure that is inexpensive and that allows obtaining a density of TSVs per unit area such that a spacing between two TSVs is less than 300 nm.

### OBJECT OF THE INVENTION

The present invention aims to propose a solution which addresses all or part of the aforementioned problems.

This aim can be achieved by implementing a method for manufacturing an electrical interconnection structure comprising:
a step of providing an initial structure, said initial structure comprising:
   a substrate having an upper face and a lower face opposite the upper face;
   at least one electrically conductive lower element arranged on the side of the lower face of the substrate;
   at least one cavity formed in the substrate and comprising an upper orifice emerging on the side of the upper face of the substrate, said at least one cavity having an inner wall internally defining an access to the lower element from the upper face of the substrate;
   an electrically insulating layer comprising an upper portion arranged on the upper face of the substrate and a vertical portion arranged on the inner wall of said at least one cavity the electrically insulating layer comprising a chamfer arranged between the upper portion and the vertical portion ;
a step of forming an interconnection element, in which an electrically conductive material is deposited on the side of the upper face of the substrate so as to form said interconnection element in the cavity, the interconnection element being in electrical connection with the lower element on the one hand and emerging via the upper orifice on the side of the upper face of the substrate on the other hand, said interconnection element comprising a through part in the cavity, an excess layer of the same conductive material as that of the through part and covering the upper portion of the electrically insulating layer;
a primary polishing step, in which the excess layer of the interconnection element is removed by chemical-mechanical polishing using a primary polishing agent; then
a final polishing step, in which a portion of the interconnection element and at least one part of the upper portion of the electrically insulating layer are simultaneously removed by chemical-mechanical polishing using a final polishing agent, thereby forming the electrical interconnection structure, the final polishing step being implemented until a thickness of the electrically insulating layer removed by chemical-mechanical polishing is greater than or equal to a height of the chamfer.

The previously described arrangements allow proposing a manufacturing method allowing forming an electrical interconnection structure with a high density of TSVs passing through the silicon.

The manufacturing method may further have one or more of the following features, taken alone or in combination.

According to one embodiment, the substrate is a silicon substrate

According to one embodiment, the through part of the interconnection element is a Through Silicon Via (TSV).

In general, the upper face of the substrate is seen in a plane that is generally disposed horizontally. Thus, by “vertical portion” it should be understood a portion extending in a direction transverse to the upper face of the substrate. This direction may, for example, be substantially perpendicular to a plane of extension of the upper face of the substrate.

According to one embodiment, the step of forming the interconnection element comprises:
the formation of a through part in the cavity; and
the formation of an excess layer of the same conductive material as that of the through part and covering the upper portion of the electrically insulating layer.

Thus, it is possible to ensure that the interconnection element passes through all the layers forming the initial structure and emerges from the cavity beyond the electrically insulating layer.

According to one embodiment, the primary polishing agent is different from the final polishing agent.

According to one embodiment, the final polishing step is implemented until the thickness of the electrically insulating layer removed by chemical-mechanical polishing is equal to the height of the chamfer. In other words, the final polishing step is implemented until removal of the chamfer.

In this way, it is possible to obtain an interconnection element in which the through parts 41 do not have an increase in diameter at the upper orifice. Furthermore, it is possible to guarantee the presence of an electrically insulating layer thickness that is sufficiently large to ensure electrical insulation on either side of the upper portion of the electrically insulating layer.

In general, the height of the chamfer is measured transversely to the upper face of the substrate, and in particular perpendicular to the upper face of the substrate.

According to one embodiment, the step of forming the interconnection element further comprises forming a barrier layer disposed between the interconnection element and the electrically insulating layer.

According to one embodiment, the final polishing step comprises the following two successive sub-steps:
a first final polishing sub-step in which a portion of the interconnection element and a portion of the barrier layer are simultaneously removed by chemical-mechanical polishing using the final polishing agent; then
a second final polishing sub-step in which a portion of the interconnection element, a portion of the barrier layer, and at least part of the upper portion of the electrically insulating layer are simultaneously removed by chemical-mechanical polishing using the final polishing agent.

According to one embodiment, during the primary polishing step, the primary polishing agent comprises:
88% to 98% by weight of deionized water;
1% to 5% by weight of silica;
1% to strictly less than 5% by weight of 1,2,4-triazole;
0.1% to 1% by weight of ethylene glycol.

According to one embodiment, the manufacturing method further comprises a step of producing interconnection pads implemented after the final polishing step, in which at least one interconnection pad is produced directly above the interconnection element, on the side of the upper face.

Thus, it is possible to make electrical contacts at the interconnection elements emerging from the substrate.

In other words, an interconnection pad can be formed in alignment with each through part 43 of the interconnection element.

According to one embodiment, during the step of forming the interconnection element, the deposited material comprises copper, tungsten, niobium, tantalum, nickel, aluminum, or any other material suitable for producing a through interconnection element.

In this way, it is possible to obtain an interconnection element with good electrical conduction properties.

According to one embodiment, the electrically insulating layer comprises silicon oxide.

This type of insulating material is easy to deposit and has a low cost.

According to one embodiment, during the step of providing the initial structure, the initial structure comprises a plurality of cavities formed in the substrate, the step of forming the interconnection element then comprising the formation of a plurality of through parts in said cavities.

In this way, at the end of the final polishing step, it is possible to form a structure comprising a plurality of TSVs, where each TSV corresponds to one of the through parts of the interconnection element.

According to one embodiment, the removal of the excess layer during the primary polishing step allows forming a plurality of TSVs, where each TSV corresponds to one of the through parts, each TSV being in electrical connection with one of the lower elements on the one hand and emerging on the side of the upper face of the substrate on the other hand.

Thus, the manufacturing method is suitable for the formation of a high-density TSV-based electrical interconnection structure, where the deposition of the TSV-forming material in the cavities is carried out collectively in all the cavities.

According to one embodiment, during the step of providing the initial structure, each cavity is separated from at least one other of the cavities by a distance which is strictly less than 10 μm, preferably strictly less than 5 μm, and preferably strictly less than 1 μm.

The manufacturing method is therefore suitable for the manufacture of a high-density electrical interconnection structure.

According to one embodiment, during the final polishing step, the final polishing agent comprises:
68 to 84% by mass of deionized water;
15 to 30% by mass of silica;
1 to 2% by mass of organic matter.

Advantageously, it has been found that the use of such a final polishing agent allows making the removal of material during the final polishing step less selective.

### BRIEF DESCRIPTION OF THE DRAWINGS

Other aspects, aims, advantages and features of the invention will appear better on reading the following detailed description of preferred embodiments thereof, given as a non-limiting example, and made with reference to the appended drawings in which:

FIG. 1 is a detailed schematic view of a succession of steps leading to the provision of the initial structure according to a particular embodiment of the invention.

FIG. 2 is a schematic view of the step of providing the initial structure and the step of forming the interconnection element according to a particular embodiment of the invention.

FIG. 3 is a schematic view of the primary polishing step and the final polishing step according to a particular embodiment of the invention.

FIG. 4 is a schematic view of the step of producing interconnection pads according to a particular embodiment of the invention.

FIG. 5 is a schematic view showing the top of an interconnection structure manufactured according to the prior art (A) and the top of an interconnection structure obtained according to a particular embodiment of the invention (B).

FIG. 6 is a schematic view of the primary polishing step and the final polishing step according to a particular embodiment of the invention.

### DETAILED DESCRIPTION

In the figures and in the following description, the same references represent identical or similar elements. In addition, the various elements are not represented to scale so as to favor clarity of the figures. Furthermore, the various embodiments and variants are not mutually exclusive and can be combined with each other.

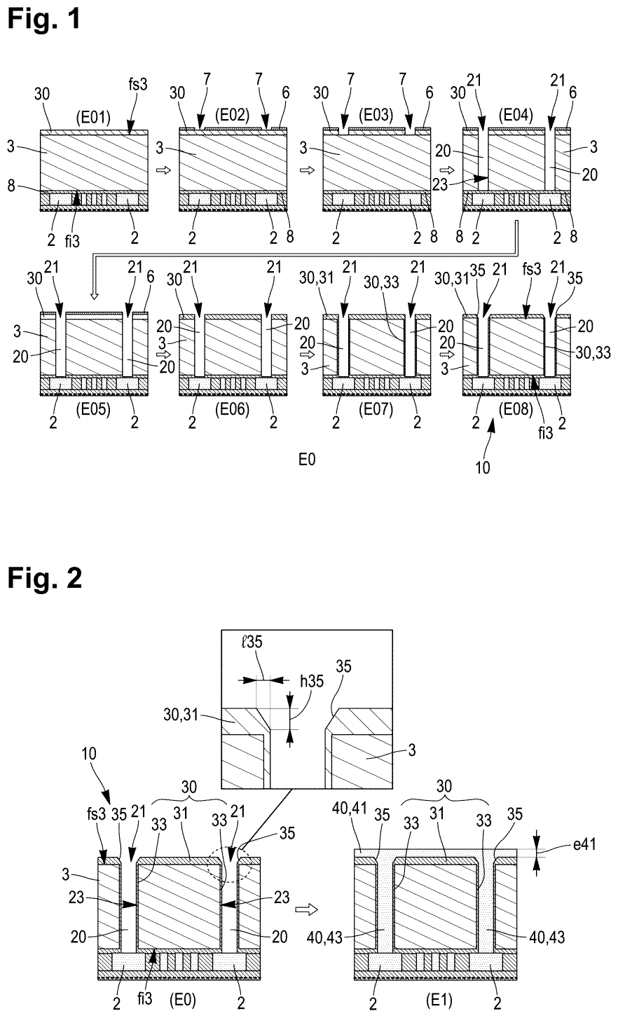

As can be seen in FIGS. 1 to 4, the invention concerns a method for manufacturing an electrical interconnection structure 1.

The manufacturing method firstly comprises a step of providing E0 an initial structure 10. FIG. 1 illustrates a non-limiting embodiment showing the succession of technological steps allowing leading to the provision E0 of the initial structure 10.

This embodiment firstly provides the provision E01 of an initial stack comprising a substrate 3 having an upper face fs3 and a lower face fi3 opposite the upper face fs3. For example, this substrate 3 may be a silicon substrate.

In general, the upper face fs3 of the substrate 3 is seen in a plane that is disposed horizontally. Thus, to facilitate understanding and description of the figures, the terms “horizontal” or “vertical” will be used in the following description, referring to the orientation of the elements described relative to the elongation plane of the substrate 3. However, these terms are not limiting as to the orientation of the elements in space. Similarly, the terms “above” or “below” are used in the following description to locate the elements according to the direction in which they are shown in the figures. However, these terms do not in any way prejudge their relative arrangement with respect to gravity in the final use of the electronic device.

The initial stack also comprises at least one electrically conductive lower element 2 arranged on the side of the lower face fi3 of the substrate 3, that is to say below the substrate according to the represented embodiment. In FIG. 1 in particular, the initial stack represents two lower elements 2. It is, however, well understood that in the field of application considered, the number of lower elements is much greater. Although this is not limiting, a lower insulating layer 8 may be disposed between the lower face fi3 of the substrate 3 and the lower element 2.

The initial stack also comprises an electrically insulating layer 30 disposed on the upper face fs3 of the substrate 3. The electrically insulating layer 30, also called insulating layer 30 is therefore disposed on the side opposite the lower elements 2 relative to the substrate 3. This insulating layer 30 can advantageously comprise silicon oxide. This type of insulating material is easy to deposit and has a low cost.

During step E02, a resin layer 6 can be deposited on the insulating layer 30, then exposed and developed by photolithography, in order to form openings 7 in the resin layer 6. In general, such a step E02 is carried out so that an opening 7 is formed in alignment with each lower element 2 at which a through access must be made.

Several etching steps can then be implemented to form an access to the lower elements 2 from the upper face fs3 of the substrate 3. Firstly, step E03 consists in extending, by etching, the openings 7 in the insulating layer 30. Step E04 is then implemented to etch the material constituting the substrate 3, to extend the openings 7 vertically, and thus form a channel in the substrate 3. Such a step can for example be implemented by Deep Reactive Ion Etching (DRIE). Generally, the channels thus formed have a generally cylindrical shape which extends vertically through the substrate 3 between the upper face fs3 and the lower face fi3.

In the case where a lower insulating layer 8 is present, an etching step E05 can be implemented to remove portions of this lower insulating layer 8 disposed above the lower elements 2. The result of steps E02 to E04 (or even E05) is to enable the formation of at least one cavity 20 formed in the substrate 3, and in particular a plurality of cavities 20 formed in the substrate 3. Each of the cavities then comprises an upper orifice 21 emerging on the side of the upper face fs3 of the substrate 3 and an inner wall 23.

Step E06 can then be implemented to remove the resin layer 6.

During step E07, an insulating material, for example silicon oxide, is deposited so that the insulating layer 30 comprises an upper portion 31 arranged on the upper face fs3 of the substrate 3 and a vertical portion 33 arranged on the inner wall 23 of said at least one cavity 20. By “vertical portion 33” it should be understood a portion extending in a direction transverse to the upper face fs3 of the substrate 3. This direction may for example be substantially perpendicular to a plane of extension of the upper face fs3 of the substrate 3. In this way, it is possible to electrically insulate the substrate 3 from any conductive element formed in the cavity 20.

At the end of step E07, portions of insulating layer 30 are disposed at the bottom of each cavity 20 and electrically insulate the lower elements 2 from the space formed inside the cavity 20. An etch back step E08 must therefore be carried out to etch said portions at the bottom of the cavity 20 and thus allow access to the lower elements 2. During this etch back step E08, a chamfer 35, or facet, is generally formed in the insulating layer 30. Thus, for each cavity 20, a chamfer 35 is arranged between the upper portion 31 and the vertical portion 33 of the insulating layer 30.

As can be seen in FIG. 2, each chamfer 35 can be characterized by a height h35 of chamfer 35 measured transversely to the upper face fs3 of the substrate 3, and in particular perpendicular to the upper face fs3 of the substrate 3; and by a width l35 of chamfer 35 measured perpendicular to said chamfer height h35. In order to better visualize these dimensions l35 and h35, FIG. 2 shows an enlargement of an area having chamfers 35.

As we will see later, in order to increase the density of the electrical connections between the upper face fs3 and the lower face fi3 of the substrate 3, it may be provided that each cavity 20 is separated from at least one other of the cavities 20 by a distance which is strictly less than 10 μm, preferably strictly less than 5 μm, and preferably strictly less than 1 μm. Such a distance may therefore be provided in step E02. The manufacturing method may therefore be suitable for the manufacture of a high-density electrical interconnection structure 1.

All the steps E01 to E08 have a particular embodiment for implementing the step of providing the initial structure 10. These steps E01 to E08 therefore lead to the formation of the initial structure 10 comprising:
the substrate 3;
the lower elements 2 arranged on the side of the lower face fi3 of the substrate 3;
the cavities 20 formed in the substrate 3, each comprising an upper orifice 21 emerging on the side of the upper face fs3 of the substrate 3, and having an inner wall 23 internally defining an access to one of the lower elements 2 from the upper face fs3 of the substrate 3; and
the electrically insulating layer 30 comprising an upper portion 31 arranged on the upper face fs3 of the substrate 3 and for each cavity 20, a vertical portion 33 arranged on the inner wall 23 of said cavity 20, as well as a 35 chamfer arranged between the upper portion 31 and the vertical portion 33 of the insulating layer 30.

Referring now to FIG. 2, the manufacturing method may comprise a succession of steps leading to the formation E1 of an interconnection element 40, in which an electrically conductive material is deposited on the side of the upper face fs3 of the substrate 3 so as to form said interconnection element 40 in the cavities 20. For example, this step of forming E1 an interconnection element may be implemented by Electrochemical Deposition (ECD), generally preceded by the conformal deposition of a barrier layer (for example titanium nitride and titanium (TiN/Ti)) and a seed layer of a material corresponding to that which must be deposited by electrochemical deposition, for example copper. The deposited material may in particular comprise at least one chemical element selected from the group consisting of copper, tungsten, niobium, tantalum, nickel, or aluminum. In this way, it is possible to obtain an interconnection element 40 with good electrical conduction properties.

The step of forming E1 the interconnection element 40 may in particular comprise the formation of a through part 43 in each of the cavities 20; and the formation of an excess layer 41 of the same conductive material as that of the through part 43 and covering the upper portion 31 of the electrically insulating layer 30. It is therefore well understood that during the step of forming E1 the interconnection element 40, it is possible to form a plurality of through parts 43, connected to each other by the excess layer 41. Thus, it is possible to ensure that the interconnection element 40, and in particular that each through part 43 passes through all the layers forming the initial structure 10, and emerges from the corresponding cavities 20 beyond the electrically insulating layer 30. Thus, the step of forming E1 the interconnection element 40 may comprise the formation of a plurality of through parts 43.

As a result, the interconnection element 40 is in electrical connection with the lower element 2 on the one hand and emerges via the upper orifice 21 on the side of the upper face fs3 of the substrate 3 on the other hand. It is therefore well understood that the through parts 43 of the interconnection element will ultimately ensure an electrical connection through the thickness of the substrate 3. In other words, the through parts of the interconnection element 40 are intended to form Through Silicon Vias (TSVs) at the end of the manufacturing method.

According to an alternative, shown in FIG. 6, during the step of forming E1 of the interconnection element 40, a barrier layer 38 may be deposited, and arranged between the interconnection element 40 and the insulating layer 30. This barrier layer 38 may in particular be made of titanium/titanium nitride Ti/TiN.

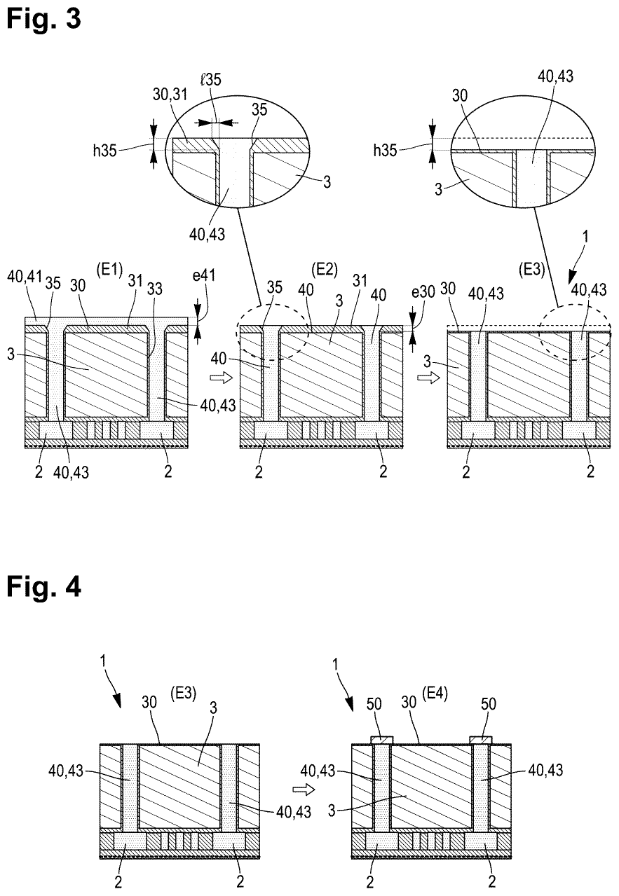

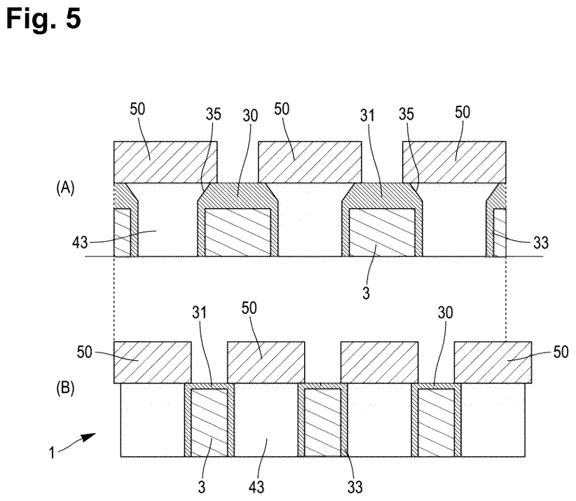

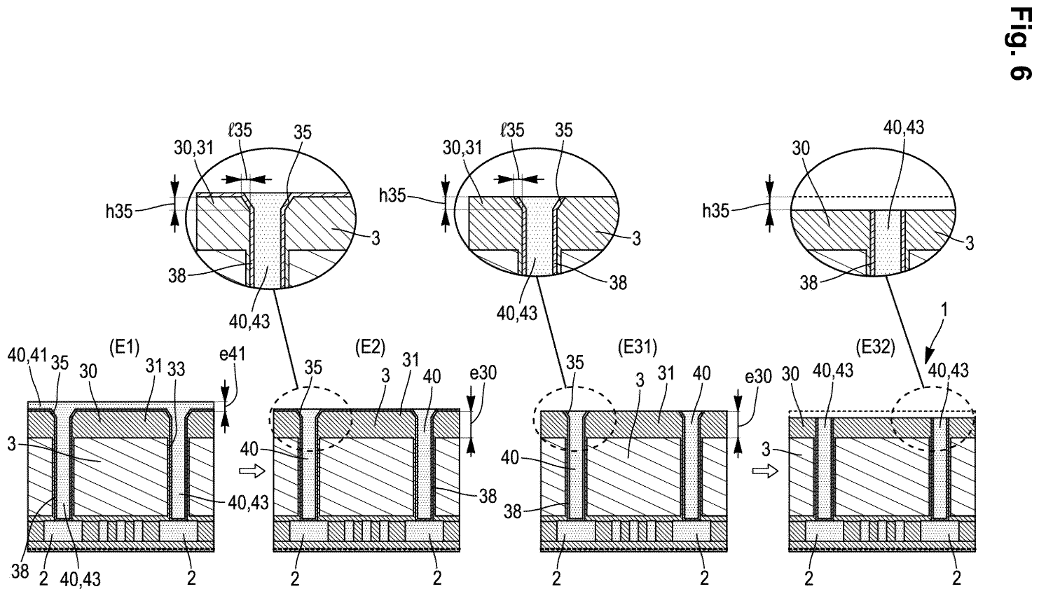

As illustrated in FIGS. 3 and 5, the manufacturing method further comprises a primary polishing step E2, implemented after the step of forming E1 the interconnection element 40, in which the excess layer 41 of the interconnection element 40 is removed by chemical-mechanical polishing using a primary polishing agent. In this way, it is possible to carry out a primary polishing allowing removing a thickness e41 of material from the interconnection element 40 corresponding to the thickness of the excess layer 41.

For example, if the material of the interconnection element 40 comprises copper, the primary polishing step E2 comprises removing only the copper. It is possible, for example, to stop the primary polishing step E2, by magnetic detection, when the excess layer 41 has been completely removed. When the structure includes a barrier layer 38, it is possible to stop the primary polishing step E2 at the barrier layer 38.

According to one embodiment, the primary polishing agent may comprise:
88% to 98% by weight of deionized water;
1% to 5% by weight of silica;
1% to strictly less than 5% by weight of 1,2,4-Triazole;
0.1% to 1% by weight of ethylene glycol.

The removal of the excess layer 41 during the primary polishing step E2 allows forming a plurality of TSVs, where each TSV corresponds to one of the through parts 43. Each TSV is in electrical connection with one of the lower elements 2 on the one hand and emerging on the side of the upper face fs3 of the substrate 3 on the other hand. Thus, the manufacturing method is suitable for the formation of an electrical interconnection structure 1 with several TSVs, where the deposition of the TSV-forming material is carried out collectively in all the cavities 20.

FIG. 3 also illustrates the implementation of a final polishing step E3, in which a portion of the interconnection element 40 and at least one part of the upper portion 31 of the electrically insulating layer 30 are removed simultaneously by chemical-mechanical polishing using a final polishing agent, thereby forming the electrical interconnection structure 1. For example, the final polishing agent may comprise:
68 to 84% by mass of deionized water;
15 to 30% by mass of silica;
1 to 2% by mass of organic matter.

Advantageously, it has been found that the use of such a final polishing agent allows making the removal of material during the final polishing step E3 less selective.

In general, the primary polishing agent is different from the final polishing agent. Thus, the primary polishing step E2 is implemented before carrying out the final polishing step E3 which is specific to the simultaneous removal of two (or three) materials. It is thus possible to adapt the type of polishing agent to the type of chemical-mechanical polishing carried out. However, it is possible for the final polishing agent to be the same as the primary polishing agent. In this case, the final polishing step E3 and the primary polishing step E2 are implemented successively, but during the same operation.

FIG. 6 illustrates a variant in which the final polishing step E3 is implemented in two successive sub-steps:
a first final polishing sub-step E31 in which a portion of the interconnection element 40 and a portion of the barrier layer 38 are simultaneously removed by chemical-mechanical polishing using the final polishing agent; then
a second final polishing sub-step E32 in which a portion of the interconnection element 40, a portion of the barrier layer 38, and at least part of the upper portion 31 of the electrically insulating layer 30 are simultaneously removed by chemical-mechanical polishing using the final polishing agent.

For example, the first final polishing sub-step E31 may be stopped after a given time, or by detecting a change in mechanical torque. The second final polishing sub-step E32 may be stopped after a given time.

The final polishing step E3 is implemented until a thickness e30 of the electrically insulating layer 30 removed by chemical-mechanical polishing is greater than or equal to a height h35 of the chamfer 35. More particularly, the final polishing step E3 may be implemented until the thickness e30 of the electrically insulating layer 30 removed by chemical-mechanical polishing is equal to the height h35 of the chamfer 35. In other words, the final polishing step E3 is implemented until removal of the chamfer 35.

The previously described arrangements allow obtaining an interconnection element 40 in which the through parts 43 do not have an increase in diameter at the upper orifice 21. Furthermore, it is possible to guarantee the presence of a remaining electrically insulating layer 30 thickness that is sufficiently large to ensure electrical insulation on either side of the upper portion 31 of the electrically insulating layer 30.

At the end of the primary polishing step E2 and/or the final polishing step E3, a structure is formed, comprising a plurality of TSVs, where each TSV corresponds to the through parts 43.

Finally, the manufacturing method may comprise a succession of steps leading to the production E4 of interconnection pads 50. The production E4 of the interconnection pads is implemented after the final polishing step E3 illustrated in FIG. 4. During this step, at least one interconnection pad 50 is produced directly above the interconnection element 40, on the side of the upper face fs3. In other words, an interconnection pad 50 may be formed in alignment with each through part 43 of the interconnection element 40. Thus, it is possible to make electrical contacts at the through parts 43 emerging from the substrate 3. Schematically, FIG. 5 illustrates a comparison between the top of an electrical interconnection structure 1 manufactured according to the prior art (A) and the top of an electrical interconnection structure 1 obtained according to a particular embodiment of the invention (B).

The previously described arrangements allow proposing a manufacturing method allowing forming an electrical interconnection structure 1 with a high density of TSVs passing through the silicon.

1. A manufacturing method for manufacturing an electrical interconnection structure comprising:
a step of providing an initial structure, said initial structure comprising:
a substrate having an upper face and a lower face opposite the upper face;
at least one electrically conductive lower element arranged on the side of the lower face of the substrate;
at least one cavity formed in the substrate and comprising an upper orifice emerging on the side of the upper face of the substrate, said at least one cavity having an inner wall internally defining an access to the lower element from the upper face of the substrate;
an electrically insulating layer comprising an upper portion arranged on the upper face of the substrate and a vertical portion arranged on the inner wall of said at least one cavity, the electrically insulating layer comprising
a chamfer arranged between the upper portion and the vertical portion;
a step of forming an interconnection element, wherein an electrically conductive material is deposited on the side of the upper face of the substrate so as to form said interconnection element in the cavity, the interconnection element being in electrical connection with the lower element on the one hand and emerging via the upper orifice on the side of the upper face of the substrate on the other hand, said interconnection element comprising a through part in the cavity, and an excess layer of the same conductive material as that of the through part and covering the upper portion of the electrically insulating layer;
a primary polishing step, wherein the excess layer of the interconnection element is removed by chemical-mechanical polishing using a primary polishing agent; then
a final polishing step, wherein a portion of the interconnection element and at least one part of the upper portion of the electrically insulating layer are removed simultaneously by chemical-mechanical polishing using a final polishing agent, thereby forming the electrical interconnection structure, the final polishing step being implemented until a thickness of the electrically insulating layer removed by chemical-mechanical polishing is greater than or equal to a height of the chamfer.

2. The manufacturing method according to claim 1, wherein the step of forming the interconnection element further comprises forming a barrier layer disposed between the interconnection element and the electrically insulating layer.

3. The manufacturing method according to claim 2, wherein the final polishing step comprises the following two successive sub-steps:
a first final polishing sub-step wherein a portion of the interconnection element and a portion of the barrier layer are simultaneously removed by chemical-mechanical polishing using the final polishing agent; then
a second final polishing sub-step wherein a portion of the interconnection element, a portion of the barrier layer, and at least a part of the upper portion of the electrically insulating layer are simultaneously removed by chemical-mechanical polishing using the final polishing agent.

4. The manufacturing method according to claim 1, wherein during the primary polishing step, the primary polishing agent comprises:
88% to 98% by weight of deionized water;
1% to 5% by weight of silica;
1% to strictly less than 5% by weight of 1,2,4-triazole;
0.1% to 1% by weight of ethylene glycol.

5. The manufacturing method according to claim 1, further comprising a step of producing interconnection pads implemented after the final polishing step, wherein at least one interconnection pad is produced directly above the interconnection element, on the side of the upper face.

6. The manufacturing method according to claim 1, wherein the electrically insulating layer comprises silicon oxide.

7. The manufacturing method according to claim 1, wherein during the step of providing the initial structure, the initial structure comprises a plurality of cavities formed in the substrate, the step of forming the interconnection element then comprising the formation of a plurality of through parts in said cavities.

8. The manufacturing method according to claim 7, wherein the removal of the excess layer during the primary polishing step allows forming a plurality of TSVs, where each TSV corresponds to one of the through parts, each TSV being in electrical connection with one of the lower elements on the one hand and emerging on the side of the upper face of the substrate on the other hand.

9. The manufacturing method according to claim 1, wherein during the provision step, each cavity is separated from at least one other of the cavities by a distance which is less than 10 μm.

10. The manufacturing method according to claim 1, wherein during the final polishing step, the final polishing agent comprises:
68 to 84% by mass of deionized water;
15 to 30% by mass of silica;
1 to 2% by mass of organic matter.
